(19) United States
(12) Patent Application Publication
(10) Pub. No.: US 2022/0262723 A1
(43) Pub. Date: Aug. 18, 2022

(54) SUBTRACTIVE DAMASCENE FORMATION OF HYBRID INTERCONNECTIONS

(71) Applicant: QUALCOMM Incorporated, San Diego, CA (US)

(72) Inventors: Junjing BAO, San Diego, CA (US); John Jianhong ZHU, San Diego, CA (US); Haining YANG, San Diego, CA (US)

(21) Appl. No.: 17/176,969

(22) Filed: Feb. 16, 2021

(51) Int. Cl. H01L 23/522; H01L 23/532; H01L 23/528; H01L 21/768

(52) U.S. Cl. CPC H01L 23/5226; H01L 21/7685; H01L 23/528; H01L 23/53238

(57) ABSTRACT

An integrated circuit (IC) having an interconnect structure with metal lines with different conductive materials for different widths and a method for fabricating such an IC. An example IC generally includes an active layer and an interconnect structure disposed thereabove and comprising a plurality of metal layers and one or more vias landing on metal lines. At least one of the plurality of metal layers comprises one or more first metal lines and one or more second metal lines. The one or more first metal lines have one or more first widths and comprise a first conductive material including copper. The one or more second metal lines have one or more second widths and comprise a second conductive material different from the first conductive material, where the second widths are narrower than the first widths. The vias have one or more third widths and comprise a third conductive material.

### BACKGROUND

### Field of the Disclosure

Certain aspects of the present disclosure generally relate to electronic components and, more particularly, to integration of hybrid metal lines in a metal layer of an integrated circuit.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

As electronic devices are getting smaller and faster, the demand for integrated circuits (ICs) with higher I/O count, faster data processing rate, and/or better signal integrity greatly increases. The ICs may include various layers of conductors (e.g., metal layers) disposed between layers of dielectric material, which are formed during a back-end-of-line (BEOL) fabrication process. The conductors facilitate electrical wiring to various electrical components including transistors, amplifiers, inverters, control logic, memory, power management circuits, buffers, filters, resonators, capacitors, inductors, resistors, etc.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include desirable resistance for metal lines with different widths in a metal layer of an integrated circuit.

Certain aspects of the present disclosure provide an integrated circuit. The integrated circuit generally includes an active layer and an interconnect structure. The interconnect structure is disposed above the active layer, and the interconnect structure comprises a plurality of metal layers, where at least one of the plurality of metal layers comprises one or more first metal lines and one or more second metal lines. The one or more first metal lines have one or more first widths and comprise a first conductive material including copper. The one or more second metal lines have one or more second widths and comprise a second conductive material different from the first conductive material, where the second widths are narrower than the first widths.

Certain aspects of the present disclosure provide an integrated circuit. The integrated circuit generally includes an active layer and an interconnect structure. The interconnect structure is disposed above the active layer, and the interconnect structure comprises a plurality of metal layers and one or more vias, where at least one of the plurality of metal layers comprises one or more first metal lines and one or more second metal lines. The one or more first metal lines have one or more first widths and comprise a first conductive material including copper. The one or more second metal lines have one or more second widths and comprise a second conductive material different from the first conductive material, where the second widths are narrower than the first widths. The one or more vias have one or more third widths and comprise a third conductive material different from the first conductive material.

Certain aspects of the present disclosure provide a method of fabricating an integrated circuit. The method generally includes forming an active layer and forming an interconnect structure above the active layer. The interconnect structure comprises a plurality of metal layers and one or more vias, and at least one of the plurality of metal layers comprises one or more first metal lines and one or more second metal lines. The one or more first metal lines have one or more first widths and comprise a first conductive material including copper. The one or more second metal lines have one or more second widths and comprise a second conductive material different from the first conductive material, where the second widths are narrower than the first widths. The one or more vias have one or more third widths and comprise a third conductive material different from the first conductive material.

Certain aspects of the present disclosure provide an integrated circuit. The integrated circuit generally includes an active layer and an interconnect structure disposed above the active layer. The interconnect structure comprises a plurality of metal layers and one or more vias. At least one of the plurality of metal layers comprises: one or more first metal lines having one or more first widths wider than a particular width and comprising copper; and one or more second metal lines having one or more second widths narrower than the particular width and comprising ruthenium. The one or more vias have one or more third widths and land on at least one of the one or more first metal lines or the one or more second metal lines. For certain aspects, the vias may be composed of ruthenium, whereas in other aspects, the vias may be composed of a different metal than ruthenium.

Certain aspects of the present disclosure provide an integrated circuit. The integrated circuit generally includes an active layer and an interconnect structure. The interconnect structure is disposed above the active layer. The interconnect structure comprises a plurality of metal layers, and at least one of the plurality of metal layers comprises one or more first metal lines and one or more second metal lines. The one or more first metal lines have one or more first widths wider than a particular width and comprise copper. The one or more second metal lines having one or more second widths narrower than the particular width and comprise ruthenium.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a cross-sectional view of an example integrated circuit, in accordance with certain aspects of the present disclosure

FIGS. 2A and 2B are cross-sectional views illustrating an example metal layer and via layer of an interconnect structure with at least two different metals, in accordance with certain aspects of the present disclosure.

FIG. 3 is a cross-sectional view illustrating another example metal layer and via layer of an interconnect structure with at least three different metals, in accordance with certain aspects of the present disclosure.

FIGS. 4A-4F are cross-sectional views illustrating example operations for fabricating an interconnect structure of an integrated circuit, in accordance with certain aspects of the present disclosure.

FIG. 5 is a flow diagram illustrating example operations for fabricating an integrated circuit, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to an integrated circuit having metal lines with different conductors for different widths, as well as a method of fabricating such an integrated circuit.

In the micro-electronic technology industry, there is a continuous demand and evolution of processes, technologies, and assembly methodologies to design and implement smaller, more efficient integrated circuits (ICs). To achieve the smaller IC size, the IC may be fabricated with fine architectural designs inside and outside a package. In certain cases, copper (Cu) may be used as the conductive material for various metal lines of a metal layer. In order to facilitate deposition of the copper and reduce electromigration (EM) of the copper, a barrier-seed layer may be initially deposited in cavities in dielectric layers of the IC. With continuous scaling, for example, in cases where the metal pitch is less than 25 nm, copper metal lines may exhibit an increased resistance compared to other conductive materials. As the metal pitch decreases, the barrier-seed layer may take a greater proportion of a metal line, affecting the scaling and electrical properties of the metal line. Other conductive materials, which have desirable resistance and/or lack the barrier-seed layer, may be used for the metal lines.

Aspects of the present disclosure provide an integrated circuit having metal lines with different conductors for different widths, such as copper for wide power rails and ruthenium (Ru) for narrower metal lines. That is, the selection of conductive material for metal lines in a metal layer may depend on the width of a given metal line. For example, ruthenium may be used for metal lines having a width less than 12 nanometers (nm), and copper may be used for metal lines having a width greater than or equal to 12 nm. Subtractive methods may be used to pattern molds for copper deposition and the formation of the narrower metal lines to provide a desirable grain size for low resistances. The wide copper metal lines and the narrower metal lines may be formed at the same height to provide a desirable resistance. The selection of conductive material based on metal line width may enable a conductive material having a desirable resistance in the narrower metal lines and another conductive material having a desirable resistance in the wider metal lines.

In certain aspects, ruthenium (Ru), cobalt (Co), rhodium (Rh), nickel (Ni), aluminum (Al), and/or molybdenum (Mo) may be used in vias landing on the metal lines. These conductive materials may also enable a desirable resistance for the vias, for example, due to the vias being without a barrier layer or due to there being a thin adhesion layer at the via bottom.

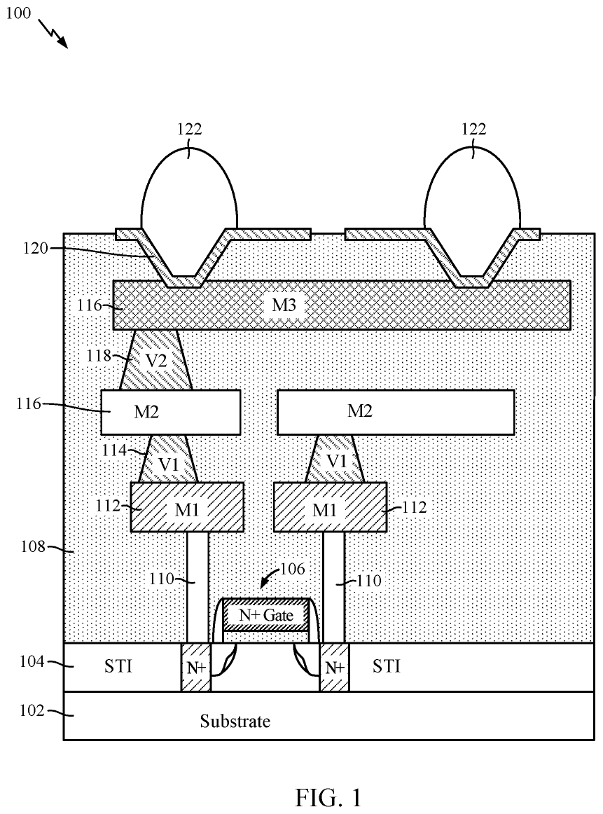

FIG. 1 is a cross-sectional view of an example integrated circuit 100 having hybrid interconnections, in accordance with certain aspects of the present disclosure. As shown, the integrated circuit 100 may include a substrate 102, a dielectric region 104, an active electrical device 106 (e.g., a transistor), one or more dielectric layers 108, local conductive interconnects 110 (e.g., source-drain conductive contacts which are often abbreviated as CA), a first layer of metal lines 112 (e.g., metal layer one—M1), and first conductive vias 114 (e.g., first vias—V1). In certain aspects, the integrated circuit 100 may include additional layers of metal lines 116 (e.g., metal layer two—M2, and metal layer three—M3), additional conductive vias 118 (e.g., via layer two—V2), under-bump conductive pads 124, and solder bumps 126.

The substrate 102 may be, for example, a portion of a carrier or semiconductor wafer such as a carrier or wafer comprising silicon (Si), silicon carbide (SiC), sapphire, diamond, or other suitable substrate materials. The dielectric region 104 may be disposed above the substrate 102. The dielectric region 104 may comprise an oxide, such as silicon dioxide (SiO₂). In aspects, the dielectric region 104 may be a shallow trench isolation (STI) region configured to electrically isolate the active electrical device 106 from other electrical components, such as other active electrical devices (not shown) arranged above the substrate 102.

The active electrical device 106 may be disposed above the substrate 102. In this example, the active electrical device 106 may include one or more transistors such as metal-oxide-semiconductor field-effect transistors (MOSFETs). In aspects, although depicted as a planar transistor, the active electrical device 106 may include one or more multi-gate or non-planar transistors, such as fin field effect transistors (finFETs) and/or gate-all-around (GAA) FETs. In certain aspects, the active electrical device 106 may be an inverter, amplifier, and/or other suitable electrical devices comprising transistors. The local conductive interconnects 110 may be electrically coupled to the active electrical device 106. For example, the source and/or drain of the active electrical device 106 may be electrically coupled to the local conductive interconnects 110, which are electrically coupled to the first layer of metal lines 112. In certain aspects, the active electrical device 106 may be formed during a front-end-of-line (FEOL) fabrication process.

The first layer of metal lines 112 and the first conductive vias 114 may be disposed above electrical components (e.g., the active electrical device 106) and formed during a back-end-of-line (BEOL) fabrication process of the integrated circuit 100. The first layer of metal lines 112 may be implemented as conductive traces embedded in at least one of the dielectric layers 108. For certain aspects, the first conductive vias 114 may be embedded in at least one of the dielectric layers 108, which may include a dielectric material such as silicon dioxide or silicon nitride.

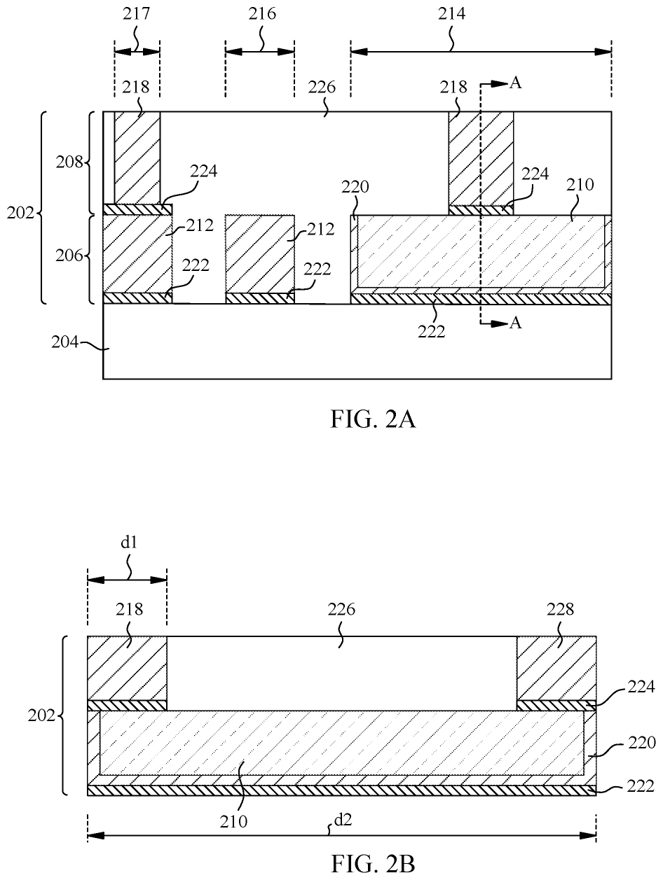

In aspects, the first layer of metal lines 112 may have a conductive material that depends on the width of the metal lines as further described herein with respect to FIG. 2A. For example, one of the metal lines in the first layer may have copper, and another of the metal lines in the first layer may have ruthenium (Ru), cobalt (Co), rhodium (Rh), nickel (Ni), aluminum (Al), molybdenum (Mo), or a combination thereof, for example, due to this metal line being narrower than the copper metal line. The selection of conductive material for the metal lines in a metal layer based on width may enable desirable resistances for metal lines of varying width. The first layer of metal lines 112, which employs width-dependent conductive materials, may be the closest metal layer disposed above the active electrical device 106, and at least one of additional layers of metal lines 116 may be the next closest metal layer disposed above the active electrical device 106. The conductive material for the additional layers of metal lines 116 may be selected based on width, or the same conductive material may be used throughout a single layer of the additional layers of metal lines 116.

The layers of metal lines 112, 116 and conductive vias 114, 118 provide electrical routing between the active electrical device 106 and other electrical components (not shown), including, for example, capacitors, inductors, resistors, an integrated passive device, a power management IC (PMIC), a memory chip, etc. In aspects, the additional conductive vias 118 and additional layers of metal lines 116 may be embedded in the dielectric layers 108 and formed during the BEOL fabrication process of the integrated circuit 100.

In this example, the integrated circuit 100 may be a flip-chip ball grid array (FC-BGA) integrated circuit having multiple solder bumps 122 electrically coupled to the under-bump conductive pads 120. The solder bumps 122 may enable electrical coupling between the integrated circuit 100 and various other electrical devices or components, such as a package substrate, an interposer, a circuit board, etc. In certain cases, additionally or alternatively, the integrated circuit 100 may have conductive pillars (e.g., copper (Cu) pillars) that electrically couple the integrated circuit 100 to a package substrate, an interposer, or a circuit board, for example.

### Example Width-Dependent Conductor for Metal Lines

FIG. 2A is a cross-sectional view illustrating an example interconnect structure 202 disposed above an active layer 204 of an integrated circuit (e.g., the integrated circuit 100), in accordance with certain aspects of the present disclosure. The interconnect structure 202 may include a plurality of metal layers, such as the first layer of metal lines 112 and the additional layers of metal lines 116 depicted in FIG. 1. As shown, the interconnect structure 202 includes a metal layer 206, and in certain cases, a via layer 208. In certain aspects, the metal layer 206 and via layer 208 may correspond to the first layer of metal lines 112 and the conductive vias 114, respectively, as described herein with respect to FIG. 1. Expressed another way, the metal layer 206 may be the closest metal layer to the active layer 204, where additional metal layers may be disposed above the metal layer 206. In other aspects, there may be one or more metal layers between the metal layer 206 and the active layer 204. In aspects, the metal layer 206 may be arranged as a front-side or a back-side metal layer relative to the active layer 204.

The metal layer 206 includes one or more first metal lines 210 and one or more second metal lines 212. The first metal lines 210 may have one or more first widths 214, and the second metal lines 212 may have one or more second widths 216, where second widths 216 may be narrower than the first widths 214. In certain aspects, the first widths 214 may be wider than a fourth width (e.g., a width of 12 nm or less, which may be a particular width based on resistivity versus trace width for different electrically conductive materials), and the second widths 216 may be narrower than the fourth width. Expressed another way, the first widths may be wider than a particular width, and the second widths may be narrower than the particular width. The first metal lines 210 may include a power rail. That is, the first metal lines 210 may serve as a power rail for delivering a power supply voltage such as V_{DD} or a circuit ground.

Due to the greater width, the first metal lines 210 may include a first conductive material that includes copper. The first metal lines 210 may also include a barrier layer 220 that is disposed around the first conductive material. In aspects, the barrier layer 220 may include at least one of tantalum (Ta), tantalum nitride (TaN), titanium nitride (TiN), or titanium-tungsten (TiW). In certain aspects, the barrier layer 220 may include a conductive material that reduces and/or prevents electromigration of the first conductive material. In aspects, the barrier layer 220 may serve as a seed layer when forming or depositing the first conductive material to form the first metal lines 210.

The second metal lines 212 may include a second conductive material that is different from the first conductive material. For example, the second conductive material may include ruthenium (Ru), cobalt (Co), rhodium (Rh), nickel (Ni), aluminum (Al), molybdenum (Mo), or a combination thereof. The differing conductive materials used for the first metal lines 210 and second metal lines 212 may enable a desirable resistance for these metal lines 210, 212 depending on the width of the metal lines 210, 212. In this example, the second conductive material for the second metal lines 212 is depicted as comprising ruthenium. The second metal lines 212 may carry various low power signals (such as low voltage (and/or low current) digital or analog signals), which enable a narrower width than the first metal lines 210.

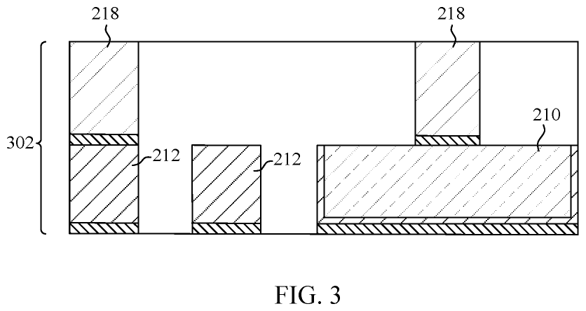

In the via layer 208, the interconnect structure 202 may further include one or more vias 218 disposed above at least one of the first metal lines 210 or the second metal lines 212. In aspects, the vias may land on the first metal lines 210 and/or the second metal lines 212. As shown, one of the vias 218 is disposed above the first metal line 210, and another of the vias 218 is disposed above one of the second metal lines 212. The vias 218 may be electrically coupled to at least one of the first metal lines 210 or the second metal lines 212. For example, each of the vias 218 depicted in FIG. 2A may be electrically coupled to the corresponding metal line 210, 212 above which the respective via 218 is disposed. The vias 218 may have one or more third widths 217, which may be less than (or equal to) the first widths 214 and/or the second widths 216. The vias 218 may include a third conductive material different from the first conductive material. For example, the third conductive material may include ruthenium (Ru), cobalt (Co), rhodium (Rh), nickel (Ni), aluminum (Al), molybdenum (Mo), or a combination thereof. For certain aspects, the third conductive material may be the same as the second conductive material. In this example, the second conductive material for the second metal lines 212 and the third conductive material for the vias 218 are depicted as comprising ruthenium. In certain aspects, the third conductive material may be different from the second conductive material, for example, as further described herein with respect to FIG. 3.

In certain aspects, a first adhesion layer 222 may be disposed between the active layer and the metal lines 210, 212 in the metal layer 206. A second adhesion layer 224 may be disposed between the metal lines 210, 212 and the vias 218 in the via layer 208. The adhesion layers 222, 224 may facilitate adhesion between the various conductive materials. For certain aspects, the adhesion layers 222, 224 may include titanium nitride (TiN), for example.

In aspects, the interconnect structure 202 may further include a dielectric material 226 such that the plurality of metal layers (including the metal layer 206) are embedded in the dielectric material 226. In aspects, the via layer 208 may also be embedded in the dielectric material 226. The dielectric material 226 may include silicon dioxide or silicon nitride. In certain aspects, the dielectric material 226 may correspond to the dielectric layers 108 as described herein with respect to FIG. 1.

In this example, the active layer 204 may include one or more layers in which an active electric device (e.g., the active electric device 106) is integrated. For example, the active layer 204 may include a substrate (e.g., the substrate 102), a dielectric region (e.g., the dielectric region 104), an active electric device (e.g., the active electric device 106), and/or local conductive interconnects (e.g., the local conductive interconnects 110).

FIG. 2B is a cross-sectional view illustrating the interconnect structure 202 along the line A-A as depicted in FIG. 2A, in accordance with certain aspects of the present disclosure. As shown, the via 218 may have a narrower depth d1 than the depth d2 of the first metal line 210, which may extend further along the depth of the integrated circuit. The via 218 may provide an electrical connection between metal layers, for example, including the metal layer 206 and another metal layer (not shown) disposed above the metal layer 206. In certain aspects, additional via(s) 228 may be arranged along the depth of the first metal line 210.

In certain aspects, the via layer may use a different conductive material than the narrower metal lines. For example, FIG. 3 is a cross-sectional view illustrating an example interconnect structure 302 disposed, in accordance with certain aspects of the present disclosure. In this example, the third conductive material for the vias 218 may include molybdenum (Mo), whereas the second conductive material for the second metal lines 212 may comprise ruthenium (Ru). Other differing metal configurations may be employed, such as the vias 218 comprising aluminum (Al), and the second metal lines comprising cobalt (Co).

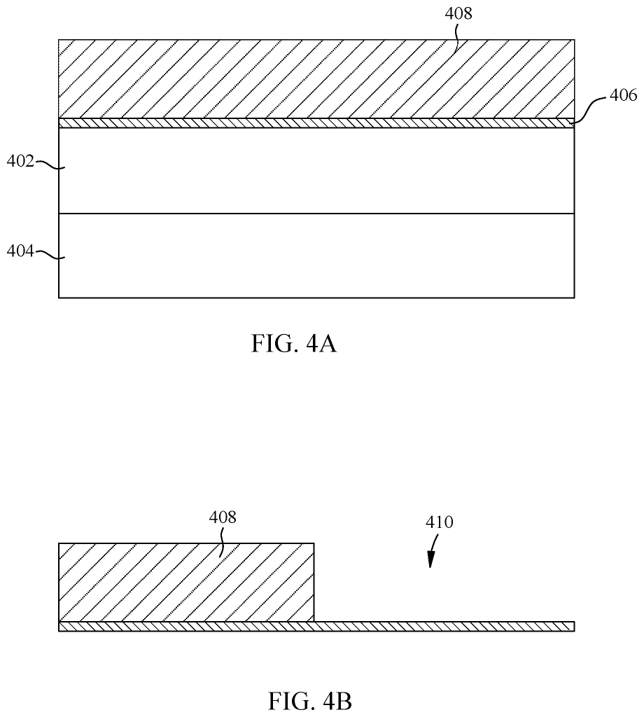

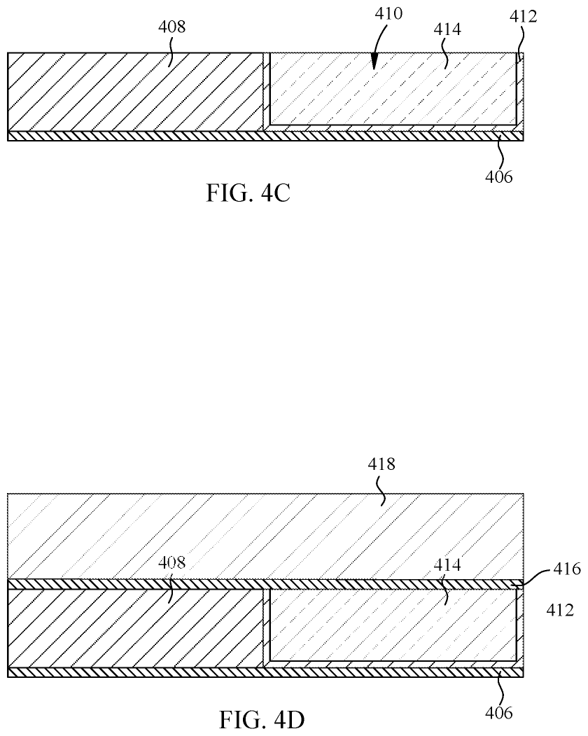

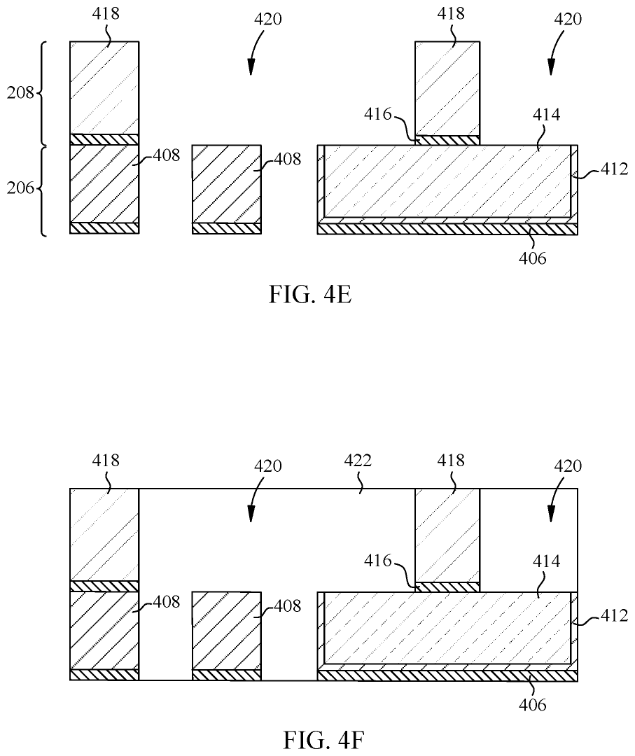

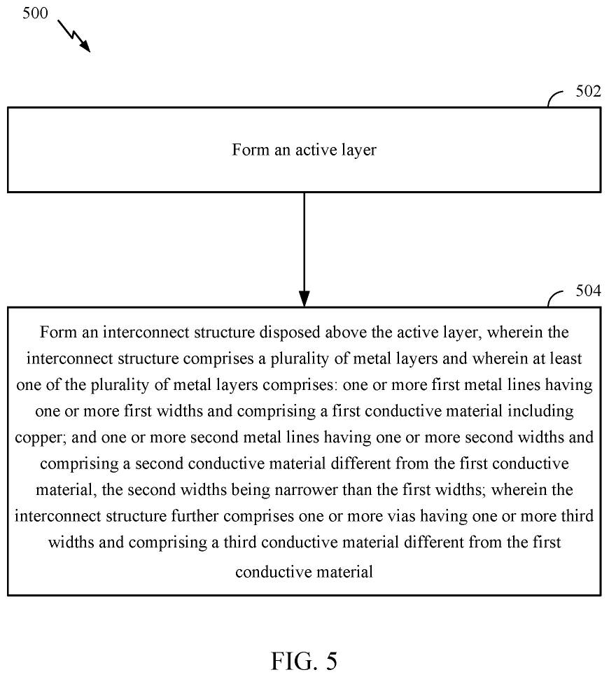

FIGS. 4A-4F illustrate example operations for fabricating an interconnect structure (e.g., the interconnect structure 202) for an integrated circuit using a subtractive damascene process, in accordance with certain aspects of the present disclosure. The operations may be performed by an integrated circuit processing facility, for example. FIGS. 4A-4F illustrate cross-sectional views of the example operations described herein. The operations may include various BEOL operations, where BEOL operations may include the operations to form various conductive connections used to interconnect electrical devices in an integrated circuit.

As shown in FIG. 4A, an active layer 402 may be formed above the substrate 404. The active layer 402 may be formed using various FEOL operations, where the FEOL operations may include the operations to form active electrical devices, such as one or more semiconductor transistors. A first adhesion layer 406 may be formed above the active layer 402, and a first conductive material 408 may be formed above the first adhesion layer 406. In certain aspects, the first adhesion layer 406 may include titanium nitride (TiN). As an example, the first adhesion layer may have a thickness of about 0.3 nm. In certain cases, the first adhesion layer 406 and the first conductive material may be grown using chemical vapor deposition (CVD). The first conductive material 408 may correspond to the second conductive material for the second metal lines 212 as described herein with respect to FIG. 2A.

Referring to FIG. 4B, one or more portions of the first conductive material 408 may be selectively removed to form one or more first cavities 410. The first cavities 410 may serve as molds for the wider metal lines (e.g., the first metal lines 210). In certain aspects, portions of the first conductive material 408 may be removed using a selective etching process, such as a reactive ion etching (RIE) process. As an example, portions of the first conductive material 408 may be etched with a chlorine (Cl₂) plasma removal etching process.

As depicted in FIG. 4C, a seed/barrier layer 412 may be formed along the surfaces of the first cavities 410, such that a portion of the seed/barrier layer 412 may be arranged adjacent to the first conductive material 408 and another portion of the seed/barrier layer 412 may be disposed above the first adhesion layer 406. The seed/barrier layer 412 may comprise tantalum nitride (TaN) or tantalum (Ta), for example. A second conductive material 414 may be formed in the first cavities 410. In aspects, the second conductive material 414 may include copper, and a plating reflow process may be used to deposit the copper in the first cavities 410. The second conductive material 414 may be different from the first conductive material 408. After forming the second conductive material 414, a planarization process (e.g., a chemical-mechanical planarization (CMP) process) may be performed to smooth and/or level the surfaces of the second conductive material 414 and the seed/barrier layer 412 with the first conductive material 408. The second conductive material 414 may correspond to the first conductive material for the first metal lines 210 as described herein with respect to FIG. 2A.

As shown in FIG. 4D, a second adhesion layer 416 may be formed above the first and second conductive materials 408, 414, and a third conductive material 418 may be formed above the second adhesion layer 416. The third conductive material 418 may be different from the second conductive material 414, but may be the same as or different from the first conductive material 408. In this example, the third conductive material 418 is molybdenum (Mo), which is different from the first conductive material 408 and the second conductive material 414. The third conductive material 418 may correspond to the third conductive material for the vias 218 as described herein with respect to FIG. 2A. The second adhesion layer 416 may include titanium nitride (TiN), for example. In certain cases, the second adhesion layer 416 and the third conductive material 418 may be grown using CVD.

Referring to FIG. 4E, portions of the first adhesion layer 406, portions of the first conductive material 408, portions of the second adhesion layer 416, and portions of the third conductive material 418 may be removed to form one or more second cavities 420. Portions of the first conductive material 408 may be removed such that at least one of the second cavities 420 is arranged between the remaining first conductive material 408 and the second conductive material 414. The second cavities 420 may serve as molds for a dielectric material, such as the dielectric material 226, as further described herein with respect to FIG. 4F. In certain aspects, portions of the first adhesion layer 406, portions of the first conductive material 408, portions of the second adhesion layer 416, and/or portions of the third conductive material 418 may be removed using a selective etching process, such as a reactive ion etching process. As an example, portions of the first adhesion layer 406, portions of the first conductive material 408, portions of the second adhesion layer 416, and/or portions of the third conductive material 418 may be etched with a chlorine (Cl₂) plasma removal etching process.

In aspects, the selective etching used to remove these conductive materials 408, 418 and adhesion layers 406, 416 may be referred to as a subtractive damascene or self-aligned subtractive etch. The remaining portions of the first conductive material 408 may form narrower metal lines (e.g., the second metal lines 212) in the metal layer 206, and the second conductive material 414 may form wider metal lines (e.g., the first metal lines 210) in the metal layer 206. In other words, portions of the first conductive material 408 may be etched such that the remaining portions of the first conductive material 408 have a width that is narrower than the width of the second conductive material 414, for example, as described herein with respect to FIG. 2A. The remaining portions of the third conductive material 418 may form the vias (e.g., the vias 218) in the via layer 208.

As illustrated in FIG. 4F, a dielectric material 422 may be formed in the second cavities 420. In aspects, the dielectric material 422 may include silicon dioxide or silicon nitride. The dielectric material 422 may be deposited in the second cavities 420 using CVD. A planarization process (e.g., a CMP process) may be performed to smooth and/or level the surfaces of the dielectric material 422 with the third conductive material 418.

FIG. 5 is a flow diagram illustrating example operations 500 for fabricating an integrated circuit (e.g., an integrated circuit having the interconnect structure 202 depicted in FIG. 2A) having metal lines with different conductive materials for different widths, in accordance with certain aspects of the present disclosure. The operations 500 may be performed by an integrated circuit fabrication facility, for example.

The operations 500 may begin, at block 502, by forming an active layer (e.g., the active layer 204, 402). For example, the active layer may include an active electrical device such as a metal-oxide-semiconductor field-effect transistor (MOSFET), a bipolar junction transistor (BJT), and/or a high-electron-mobility transistor (HEMT). The formation of the active layer may employ fabrication methods of forming any one of these active electrical devices.

At block 504, an interconnect structure (e.g., the interconnect structure 202) may be formed above the active layer. As described herein with respect to FIG. 2A, the interconnect structure may include a plurality of metal layers, and at least one of the metal layers may include one or more first metal lines (e.g., the first metal lines 210) and one or more second metal lines (e.g., the second metal lines 212). The first metal lines may have one or more first widths (e.g., the first widths 214) and may include a first conductive material including copper. The second metal lines may have one or more second widths (e.g., the second widths 216) and may comprise a second conductive material different from the first conductive material, where the second widths are narrower than the first widths. In certain aspects, the second conductive material may include ruthenium (Ru), cobalt (Co), rhodium (Rh), nickel (Ni), aluminum (Al), and molybdenum (Mo), or a combination thereof. The interconnect structure may further comprise one or more vias (e.g., the vias 218) having one or more third widths and comprising a third conductive material. The third conductive material may be different from the first conductive material. In this case, the third conductive material may be the same as or different from the second conductive material. For example, the third conductive material may include ruthenium (Ru), cobalt (Co), rhodium (Rh), nickel (Ni), aluminum (Al), and molybdenum (Mo), or a combination thereof.

Formation of the interconnect structure at block 504 may include formation of a metal layer for example as described herein with respect to FIGS. 4A-4C. At block 504, a first adhesion layer (e.g., the first adhesion layer 406) may be formed above the active layer. The second conductive material may be deposited above the first adhesion layer, for example, using CVD. A first portion of the second conductive material may be removed, for example, to form one or more first cavities (e.g., the first cavities 410), which may serve as molds for the wider metal lines (e.g., the first metal lines 210). The first conductive material may be formed adjacent to a remaining portion of the second conductive material, after removing the first portion of the second conductive material. That is, the first conductive material may be formed in the first cavities. In certain aspects, a seed/barrier layer (e.g., the seed/barrier layer 412) may be formed in the first cavities before depositing the first conductive material, for example, as described herein with respect to FIG. 4C. Formation of the first cavities may involve making the widths of the first cavities correspond to the first widths, which may be wider than a fourth width (e.g., 12 nm).

Formation of the interconnect structure at block 504 may further include formation of a via layer (e.g., the via layer 208), for example, as described herein with respect to FIG. 4D. At block 504, a second adhesion layer (e.g., the second adhesion layer 416) may be formed above the first conductive material and the second conductive material. The third conductive material may be deposited above the second adhesion layer, and the third conductive material may differ from the first conductive material. For example, the third conductive material may include ruthenium (Ru), cobalt (Co), rhodium (Rh), nickel (Ni), aluminum (Al), and molybdenum (Mo), or a combination thereof. The first and second adhesion layers comprise titanium nitride (TiN). In certain aspects, the second conductive material may be different from the third conductive material.

For certain aspects, the formation of the interconnect structure at block 504 may involve a subtractive damascene process, for example, as described herein with respect to FIG. 4E. At block 504, a second portion of the second conductive material may be removed, such that one or more second cavities (e.g., the second cavities 420) are formed between the first conductive material and the second conductive material. A portion of the third conductive material may be removed, such that a remaining portion of the third conductive material includes the one or more vias coupled to at least one of the one or more first metal lines or the one or more second metal lines. The removal of the second conductive material may involve leaving the second conductive material with the second widths, where the second widths may be narrower than the fourth width (e.g., 12 nm).

For certain aspects, the formation of the interconnect structure at block 504 may involve depositing a dielectric material between the remaining conductive materials (e.g., the metal lines and/or vias), for example, as described herein with respect to FIG. 4F. At block 504, a dielectric material may be added between the one or more first metal lines and the one or more second metal lines in the metal layer, and the dielectric material may be added between the vias in a via layer (e.g., the via layer 208). The dielectric material may be formed over the plurality of metal layers such that the plurality of metal layers are embedded in the dielectric material.

### Example Aspects

In addition to the various aspects described above, specific combinations of aspects are within the scope of the disclosure, some of which are detailed below:

Aspect 1. An integrated circuit comprising: an active layer; and an interconnect structure disposed above the active layer, wherein the interconnect structure comprises a plurality of metal layers and wherein at least one of the plurality of metal layers comprises: one or more first metal lines having one or more first widths and comprising a first conductive material including copper; and one or more second metal lines having one or more second widths and comprising a second conductive material different from the first conductive material, the second widths being narrower than the first widths; wherein the interconnect structure further comprises one or more vias having one or more third widths and comprising a third conductive material different from the first conductive material.

Aspect 2. The integrated circuit of Aspect 1, wherein the second conductive material comprises ruthenium (Ru), cobalt (Co), rhodium (Rh), nickel (Ni), aluminum (Al), molybdenum (Mo), or a combination thereof.

Aspect 3. The integrated circuit according to any of Aspects 1 or 2, the one or more vias are disposed above at least one of the one or more first metal lines or the one or more second metal lines and wherein the third widths are narrower than the first widths.

Aspect 4. The integrated circuit according to any of Aspects 1-3, wherein the second conductive material is different from the third conductive material.

Aspect 5. The integrated circuit of according to any of Aspects 1-3, wherein the second conductive material is the same as the third conductive material.

Aspect 6. The integrated circuit according to any of Aspects 1-5, wherein the third conductive material comprises ruthenium (Ru), cobalt (Co), rhodium (Rh), nickel (Ni), aluminum (Al), molybdenum (Mo), or a combination thereof.

Aspect 7. The integrated circuit according to any of Aspects 1-6, wherein the one or more vias are electrically coupled to the at least one of the one or more first metal lines or the one or more second metal lines.

Aspect 8. The integrated circuit of Aspect 7, further comprising an adhesion layer disposed between the one or more vias and the at least one of the one or more first metal lines or the one or more second metal lines.

Aspect 9. The integrated circuit of Aspect 8, wherein the adhesion layer comprises titanium nitride (TiN).

Aspect 10. The integrated circuit according to any of Aspects 1-9, wherein the one or more first widths are wider than a fourth width and wherein the one or more second widths are narrower than the fourth width.

Aspect 11. The integrated circuit of Aspect 10, wherein the second conductive material comprises ruthenium (Ru) and wherein the fourth width is 12 nanometers (nm) or less.

Aspect 12. The integrated circuit according to any of Aspects 1-11, wherein the one or more first metal lines comprise a power rail.

Aspect 13. The integrated circuit according to any of Aspects 1-12, wherein the interconnect structure further comprises a dielectric material such that the plurality of metal layers are embedded in the dielectric material.

Aspect 14. A method of fabricating an integrated circuit, comprising: forming an active layer; and forming an interconnect structure above the active layer, wherein the interconnect structure comprises a plurality of metal layers and wherein at least one of the plurality of metal layers comprises: one or more first metal lines having one or more first widths and comprising a first conductive material including copper; and one or more second metal lines having one or more second widths and comprising a second conductive material different from the first conductive material, the second widths being narrower than the first widths; wherein the interconnect structure further comprises one or more vias having one or more third widths and comprising a third conductive material different from the first conductive material.

Aspect 15. The method of Aspect 14, wherein forming the interconnect structure comprises: forming a first adhesion layer above the active layer; depositing the second conductive material above the first adhesion layer; removing a first portion of the second conductive material; and depositing the first conductive material adjacent to a remaining portion of the second conductive material, after removing the first portion of the second conductive material.

Aspect 16. The method according to any of Aspects 14 or 15, wherein forming the interconnect structure further comprises: forming a second adhesion layer above the first conductive material and the second conductive material; and depositing the third conductive material above the second adhesion layer.

Aspect 17. The method according to any of Aspects 14-16, wherein forming the interconnect structure further comprises: removing a second portion of the second conductive material, such that a first cavity is formed between the first conductive material and the second conductive material; and removing a portion of the third conductive material such that a remaining portion of the third conductive material includes the one or more vias coupled to at least one of the one or more first metal lines or the one or more second metal lines.

Aspect 18. The method according to any of Aspects 14-17, wherein forming the interconnect structure further comprises: adding a dielectric material between the one or more first metal lines and the one or more second metal lines; and adding the dielectric material between the one or more vias.

Aspect 19. The method according to any of Aspects 14-18, wherein forming the interconnect structure comprises forming a dielectric material over the plurality of metal layers such that the plurality of metal layers are embedded in the dielectric material.

Aspect 20. The method according to any of Aspects 14-19, further comprising forming the integrated circuit comprising any of Aspects 1-13.

Aspect 21. An integrated circuit comprising: an active layer; and an interconnect structure disposed above the active layer, wherein the interconnect structure comprises a plurality of metal layers, and wherein at least one of the plurality of metal layers comprises: one or more first metal lines having one or more first widths wider than a particular width and comprising copper; and one or more second metal lines having one or more second widths narrower than the particular width and comprising ruthenium; wherein the interconnect structure further comprises one or more vias having one or more third widths landing on at least one of the one or more first metal lines or the one or more second metal lines and comprising ruthenium.

Aspect 22. The integrated circuit of Aspect 21, the integrated circuit comprising any of Aspects 1 through 13.

Aspect 23. An integrated circuit comprising an active layer and an interconnect structure. The interconnect structure is disposed above the active layer. The interconnect structure comprises a plurality of metal layers, and at least one of the plurality of metal layers comprises one or more first metal lines and one or more second metal lines. The one or more first metal lines have one or more first widths wider than a particular width and comprise copper. The one or more second metal lines having one or more second widths narrower than the particular width and comprise ruthenium.

Aspect 24. The integrated circuit of Aspect 23, further comprising any of Aspects 1 through 13.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An integrated circuit comprising:
an active layer; and
an interconnect structure disposed above the active layer, wherein the interconnect structure comprises a plurality of metal layers and wherein at least one of the plurality of metal layers comprises:
one or more first metal lines having one or more first widths and comprising a first conductive material including copper; and
one or more second metal lines having one or more second widths and comprising a second conductive material different from the first conductive material, the second widths being narrower than the first widths;
wherein the interconnect structure further comprises one or more vias having one or more third widths and comprising a third conductive material different from the first conductive material.

2. The integrated circuit of claim 1, wherein the second conductive material comprises ruthenium (Ru), cobalt (Co), rhodium (Rh), nickel (Ni), aluminum (Al), molybdenum (Mo), or a combination thereof.

3. The integrated circuit of claim 1, wherein the one or more vias are disposed above at least one of the one or more first metal lines or the one or more second metal lines and wherein the third widths are narrower than the first widths.

4. The integrated circuit of claim 1, wherein the second conductive material is different from the third conductive material.

5. The integrated circuit of claim 1, wherein the third conductive material comprises ruthenium (Ru), cobalt (Co), rhodium (Rh), nickel (Ni), aluminum (Al), molybdenum (Mo), or a combination thereof.

6. The integrated circuit of claim 1, wherein the one or more vias are electrically coupled to the at least one of the one or more first metal lines or the one or more second metal lines.

7. The integrated circuit of claim 6, further comprising an adhesion layer disposed between the one or more vias and the at least one of the one or more first metal lines or the one or more second metal lines.

8. The integrated circuit of claim 7, wherein the adhesion layer comprises titanium nitride (TiN).

9. The integrated circuit of claim 1, wherein the one or more first widths are wider than a fourth width and wherein the one or more second widths are narrower than the fourth width.

10. The integrated circuit of claim 9, wherein the second conductive material comprises ruthenium (Ru) and wherein the fourth width is 12 nanometers (nm) or less.

11. The integrated circuit of claim 1, wherein the interconnect structure further comprises a dielectric material such that the plurality of metal layers are embedded in the dielectric material.

12. A method of fabricating an integrated circuit, comprising:
forming an active layer; and
forming an interconnect structure above the active layer, wherein the interconnect structure comprises a plurality of metal layers and wherein at least one of the plurality of metal layers comprises:
one or more first metal lines having one or more first widths and comprising a first conductive material including copper; and
one or more second metal lines having one or more second widths and comprising a second conductive material different from the first conductive material, the second widths being narrower than the first widths;
wherein the interconnect structure further comprises one or more vias having one or more third widths and comprising a third conductive material different from the first conductive material.

13. The method of claim 12, wherein the second conductive material comprises ruthenium (Ru), cobalt (Co), rhodium (Rh), nickel (Ni), aluminum (Al), and molybdenum (Mo), or a combination thereof.

14. The method of claim 12, wherein the second conductive material is the same as the third conductive material.

15. The method of claim 12, wherein forming the interconnect structure comprises:
forming a first adhesion layer above the active layer;
depositing the second conductive material above the first adhesion layer;
removing a first portion of the second conductive material; and
depositing the first conductive material adjacent to a remaining portion of the second conductive material, after removing the first portion of the second conductive material.

16. The method of claim 15, wherein forming the interconnect structure further comprises:
forming a second adhesion layer above the first conductive material and the second conductive material; and
depositing the third conductive material above the second adhesion layer.

17. The method of claim 16, wherein forming the interconnect structure further comprises:
removing a second portion of the second conductive material, such that a first cavity is formed between the first conductive material and the second conductive material; and
removing a portion of the third conductive material such that a remaining portion of the third conductive material includes the one or more vias coupled to at least one of the one or more first metal lines or the one or more second metal lines.

18. The method of claim 17, wherein forming the interconnect structure further comprises:
adding a dielectric material between the one or more first metal lines and the one or more second metal lines; and
adding the dielectric material between the one or more vias.

19. The method of claim 12, wherein forming the interconnect structure comprises forming a dielectric material over the plurality of metal layers such that the plurality of metal layers are embedded in the dielectric material.

20. An integrated circuit comprising:
an active layer; and
an interconnect structure disposed above the active layer, wherein:
the interconnect structure comprises a plurality of metal layers and one or more vias;
at least one of the plurality of metal layers comprises:
one or more first metal lines having one or more first widths wider than a particular width and comprising copper; and
one or more second metal lines having one or more second widths narrower than the particular width and comprising ruthenium; and
the one or more vias have one or more third widths and land on at least one of the one or more first metal lines or the one or more second metal lines.
